(19) United States
(12) Patent Application Publication
(10) Pub. No.: US 2025/0107278 A1
(43) Pub. Date: Mar. 27, 2025

(54) LIGHT-EMITTING DIODE AND WHITE LIGHT-EMITTING DEVICE

(71) Applicant: Bridgelux Optoelectronics (Xiamen) Co., Ltd., Xiamen (CN)

(72) Inventors: BenJie Fan, Xiamen (CN); Hung-Chih Yang, Xiamen (CN); ShuenTa Teng, Xiamen (CN); Jingqiong Zhang, Xiamen (CN)

(21) Appl. No.: 18/806,985

(22) Filed: Aug. 16, 2024

(30) Foreign Application Priority Data
Sep. 27, 2023 (CN) 2023112601677

(51) Int. Cl. H01L 33/06; H01L 33/00; H01L 33/30; H01L 33/50

(52) U.S. Cl. CPC H10H 20/812; H10H 20/81; H10H 20/8242; H10H 20/851

(57) ABSTRACT

A light-emitting diode and a white light-emitting device are provided. The light-emitting diode includes a p-type semiconductor layer, an n-type semiconductor layer, and a light-emitting stacked layer disposed therebetween. The light-emitting stacked layer includes alternately-stacked well layers and barrier layers. The light-emitting stacked layer includes one or more second, third, fourth, and fifth well layers that have different indium concentrations, such that a C2 indium concentration, a C3 indium concentration, a C4 indium concentration, and a C5 indium concentration are respectively defined, and a relationship of the indium concentrations is C5>C4>C3>C2. The light-emitting stacked layer includes an n-side proximate section, a middle section, and a p-side proximate section along a thickness direction. The third well layer is disposed in the middle section, and the third well layer is disposed between the two second well layers.

### CROSS-REFERENCE TO RELATED PATENT APPLICATION

This application claims the benefit of priority to China Patent Application No. 202311260167.7, filed on Sep. 27, 2023, in the People's Republic of China. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a light-emitting diode, and more particularly to a light-emitting diode capable of generating a broadband blue spectrum.

### BACKGROUND OF THE DISCLOSURE

A light-emitting diode (LED) is commonly used in everyday life. However, since users are no longer satisfied with its basic function of lighting up the environment, a high-quality illumination light source that also promotes well-being and comfort is now a more sought after product.

In the conventional technology, a blue light-emitting diode is usually used to excite a fluorescent powder for generating white light, and the white light can be used as an illumination light source or a display light source. Use conditions (e.g., the temperature) of the same product may vary for different users. Due to different use conditions, fluctuations of an emission spectrum of the light-emitting diode (especially a broadband light-emitting diode) are likely to occur, thereby causing each indicator of a white light source (after a wavelength conversion via the fluorescent powder) to change and deviate from production estimates.

Therefore, how to optimize changes of a broadband blue spectrum, so as to ensure the stability of a spectrum of full-spectrum white light under different use conditions, has become one of the important issues to be solved in the related art.

### SUMMARY OF THE DISCLOSURE

In response to the above-referenced technical inadequacies, the present disclosure provides a broadband blue light-emitting diode that is capable of optimizing the stability of an emission spectrum relative to the temperature, so as to improve the stability of each indicator of a full-spectrum white light source.

In order to solve the above-mentioned problems, one of the technical aspects adopted by the present disclosure is to provide a light-emitting diode, which includes a p-type semiconductor layer, an n-type semiconductor layer, and a light-emitting stacked layer. The light-emitting stacked layer is disposed between the p-type semiconductor layer and the n-type semiconductor layer. The light-emitting stacked layer includes a plurality of well layers and a plurality of barrier layers that are alternately stacked with each other. The light-emitting stacked layer includes at least one second well layer, at least one third well layer, at least one fourth well layer, and at least one fifth well layer that have different indium concentrations, such that a C2 indium concentration, a C3 indium concentration, a C4 indium concentration, and a C5 indium concentration are respectively defined, and a relationship of the indium concentrations is C5>C4>C3>C2. The light-emitting stacked layer is configured to include an n-side proximate section, a p-side proximate section, and a middle section along a thickness direction. The at least one third well layer is disposed in the middle section. When a quantity of the at least one second well layer is two and a quantity of the at least one third well layer is one, the two second well layers are respectively disposed on two sides of the third well layer. Through the above-mentioned configuration, a blue spectrum can be widened, and the stability of the blue spectrum of the light-emitting diode can be improved irrespective of changes in temperature.

In order to solve the above-mentioned problems, another one of the technical aspects adopted by the present disclosure is to provide a white light-emitting device, which includes a substrate, a light-emitting diode, and a wavelength conversion layer. The light-emitting diode is disposed on the substrate. The wavelength conversion layer covers the light-emitting diode.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1A is a schematic cross-sectional view of a white light-emitting device according to one embodiment of the present disclosure;

FIG. 1B is a schematic view showing a structure of a light-emitting diode according to one embodiment of the present disclosure;

FIG. 1C is a schematic enlarged view of a light-emitting stacked layer of the embodiment shown in FIG. 1B;

FIG. 2 is a relation diagram of indium concentrations of a light-emitting stacked layer according to a first embodiment of the present disclosure;

FIG. 3 is a waveform diagram of a blue spectrum of the embodiment shown in FIG. 2;

FIG. 4 is a relation diagram of indium concentrations of a light-emitting stacked layer according to a second embodiment of the present disclosure;

FIG. 5 is a waveform diagram of a blue spectrum of the embodiment shown in FIG. 4;

FIG. 6 is a relation diagram of indium concentrations of a light-emitting stacked layer according to a third embodiment of the present disclosure;

FIG. 7 is a waveform diagram of a blue spectrum of the embodiment shown in FIG. 6;

FIG. 8 is a relation diagram of indium concentrations of a light-emitting stacked layer according to a fourth embodiment of the present disclosure;

FIG. 9 is a waveform diagram of a blue spectrum of the embodiment shown in FIG. 8;

FIG. 10 is a relation diagram of indium concentrations of a light-emitting stacked layer according to a fifth embodiment of the present disclosure;

FIG. 11 is a waveform diagram of a blue spectrum of the embodiment shown in FIG. 10;

FIG. 12 is a waveform diagram of a blue spectrum under different temperatures according to one embodiment of the present disclosure; and

FIG. 13 is a waveform diagram of a blue spectrum under different temperatures according to another embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

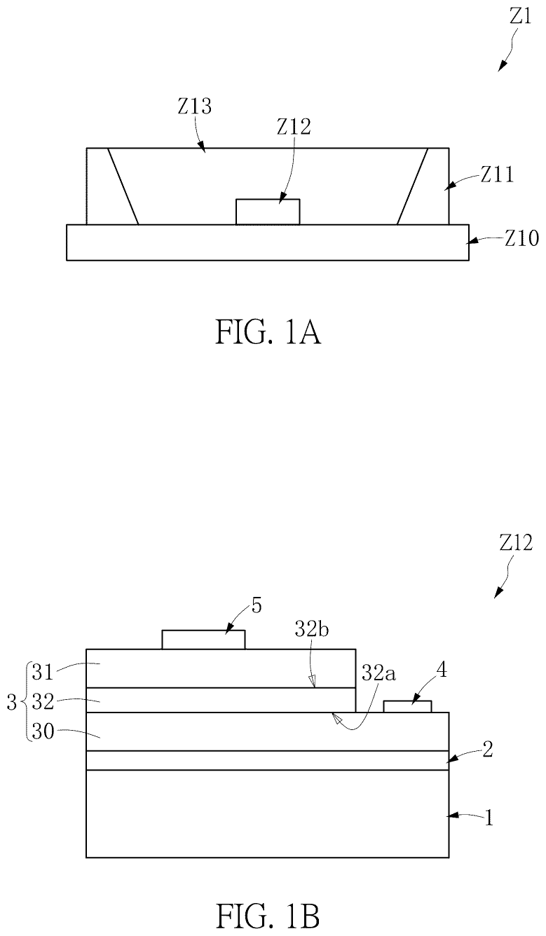

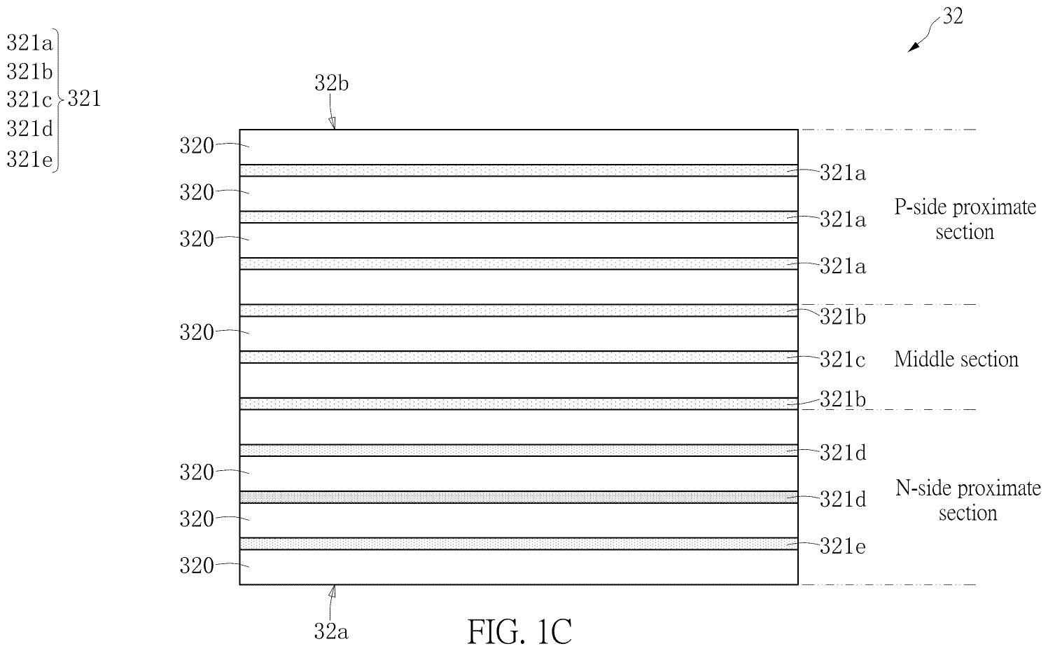

Reference is made to FIG. 1A, which is a schematic cross-sectional view of a white light-emitting device according to one embodiment of the present disclosure. In the present embodiment, a white light-emitting device Z1 is used for generating white light, especially for generating full-spectrum white light. As shown in FIG. 1A, the white light-emitting device Z1 includes a substrate Z10, a reflective assembly Z11, a light-emitting diode Z12, and a wavelength conversion layer Z13. The material of the substrate Z10 can be materials having high thermal conductivity (e.g., metal or ceramics) or composite materials. The light-emitting diode Z12 is disposed on the substrate Z10, and is used for generating a light beam having a broadband blue spectrum. A spectrum waveform of the light beam has a full width at half maximum (FWHM) that is at least greater than 30 nm. The wavelength conversion layer Z13 covers the light-emitting diode Z12. Through the wavelength conversion layer Z13, broadband blue light generated by the light-emitting diode Z12 can generate a mixed light beam (white light). The detailed structure of a light-emitting diode according to one embodiment of the present disclosure will be further illustrated below.

Referring to FIG. 1B and FIG. 1C, FIG. 1B is a schematic view showing the structure of the light-emitting diode Z12 according to one embodiment of the present disclosure, and FIG. 1C is a schematic enlarged view of a light-emitting stacked layer of the embodiment shown in FIG. 1B. The light-emitting diode Z12 of the present embodiment includes a base 1, a buffer layer 2, an epitaxial light-emitting structure 3, a first electrode 4, and a second electrode 5. The material of the base 1 can be materials that are suitable for crystal growth, such as sapphire, silicon carbide, gallium nitride, or silicon. The buffer layer 2 is formed on the base 1 by an epitaxial technique, and has a lattice constant that matches with the material of the base 1 and the material of the epitaxial light-emitting structure 3. The material of the buffer layer 2 can be aluminum nitride or gallium nitride. The epitaxial light-emitting structure 3 is disposed on the buffer layer 2, and includes an n-type semiconductor layer 30, a p-type semiconductor layer 31, and a light-emitting stacked layer 32. In the embodiment of FIG. 1B, the n-type semiconductor layer 30 is disposed on the buffer layer 2, and the light-emitting stacked layer 32 and the p-type semiconductor layer 31 are sequentially disposed on the n-type semiconductor layer 30. That is to say, the light-emitting stacked layer 32 is disposed between the N-type semiconductor layer 30 and the P-type semiconductor layer 31. In addition, the light-emitting stacked layer 32 has a first side 32a that is connected to the N-type semiconductor layer 30, and a second side 32b that is connected to the P-type semiconductor layer 31. In other embodiments, the position of the n-type semiconductor layer 30 and the position of the p-type semiconductor layer 31 are interchangeable. The first electrode 4 and the second electrode 5 are respectively and electrically connected to the n-type semiconductor layer 30 and the p-type semiconductor layer 31, so as to be electrically connected to an external control circuit during use. The structure of the light-emitting stacked layer 32 that is used for generating the above-mentioned broadband blue spectrum will be further illustrated below.

The light-emitting stacked layer 32 includes an m number of well layers 321 and an m+1 number of barrier layers 320 that are alternately stacked with each other. A direction that extends from the n-type semiconductor layer 30 to the p-type semiconductor layer 31 is defined as a thickness direction of the light-emitting stacked layer 32. The light-emitting stacked layer 32 is configured to include three sections along said thickness direction. The first three ones of the well layers 321 that are in proximity to the n-type semiconductor layer 30 and adjacent ones of the barrier layers 320 are defined as an n-side proximate section, the first three ones of the well layers 321 that are in proximity to the p-type semiconductor layer 31 and adjacent ones of the barrier layers 320 are defined as a p-side proximate section, and the well layers 321 and the barrier layers 320 that are disposed between the n-side proximate section and the p-side proximate section are defined as a middle section. In the embodiment of FIG. 1C, a quantity of the well layers 321 included in the light-emitting stacked layer 32 is nine, but the present disclosure is not limited thereto. Further details will be provided in the following embodiments. The light-emitting stacked layer 32 can include at least one second well layer 321b, at least one third well layer 321c, at least one fourth well layer 321d, and at least one fifth well layer 321e that have different indium concentrations, such that a C2 indium concentration, a C3 indium concentration, a C4 indium concentration, and a C5 indium concentration are respectively defined. A relationship of the indium concentrations is C5>C4>C3>C2. That is, out of all the well layers 321, the fifth well layer 321e has a maximum indium concentration. Taking growth variations and measurement errors of well layers into consideration, the maximum indium concentration is defined as 100%, and a difference between C5 and each of C2, C3, and C4 is 4% or more. In other words, any well layer can be deemed as the fifth well layer 321e as long as a difference between its indium concentration and the maximum indium concentration is less than 4%. Similarly, the second well layer 321b, the third well layer 321c, and the fourth well layer 321e may each have a 4% indium concentration difference from each other.

Theoretically, a concentration of indium doped in the well layer is directly related to a wavelength of light emitted by electrons and holes during a carrier recombination process in said well layer. The multiple well layers include at least four types of well layers having different indium concentrations, such that the electrons and the holes are enabled to undergo the carrier recombination process in the well layers having different indium concentrations and emit sub-light beams having different wavelengths. However, a waveform of light finally emitted by the light-emitting diode Z12 is not formed by a simple superposition of these sub-light beams. The indium concentrations, the quantity, and the position of different well layers in a light-emitting stacked layer, and a cooperative relationship between adjacent ones of the well layers are all likely to affect a waveform of a blue spectrum finally generated by the light-emitting diode Z12. In order to ensure the position and the intensity of a main peak inflection point of the broadband blue light emitted by the light-emitting diode Z12 and obtain greater stability relative to an operating temperature, the third well layer 321c of the present disclosure is disposed in the middle section of the light-emitting stacked layer 32, and the second well layer 321b is disposed on each of two sides of the third well layer 321c after numerous experiments. In some exemplary embodiments, the third well layer 321c is disposed adjacent to a middle position of the light-emitting stacked layer 32. That is, when the quantity (i.e., the number m) of the well layers 321 is an even number, the at least one third well layer 321c is disposed at a position of (m/2)+1. When the number m is an odd number, the at least one third well layer 321c is disposed at a position of (m+1)/2+1. A quantity of the at least one third well layer 321c is usually one or two, and is usually not more than three. In the present disclosure, the third well layer 321c that corresponds to a main peak of the target broadband blue spectrum within a range of between 445 nm and 475 nm is arranged to be more centrally disposed. At the same time, the second well layer 321b that corresponds to another main peak of the target broadband blue spectrum within a range of between 430 nm and 460 nm is arranged to be disposed on each of the two sides of the third well layer 321c. In this way, more electrons and holes are allowed to undergo the carrier recombination process, so to as to ensure that the quantity of photons generated during the carrier recombination process of the electrons and the holes in a thermal state will not be significantly decreased.

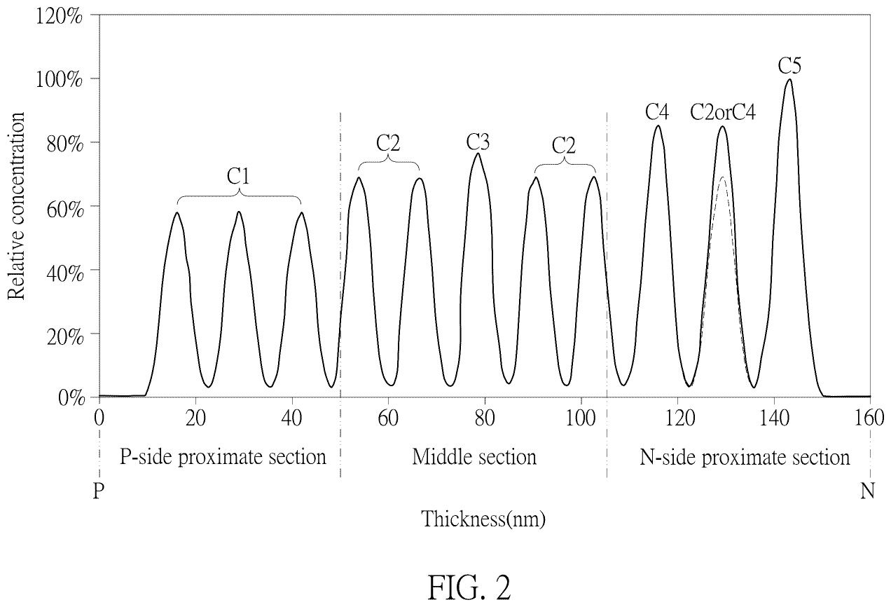

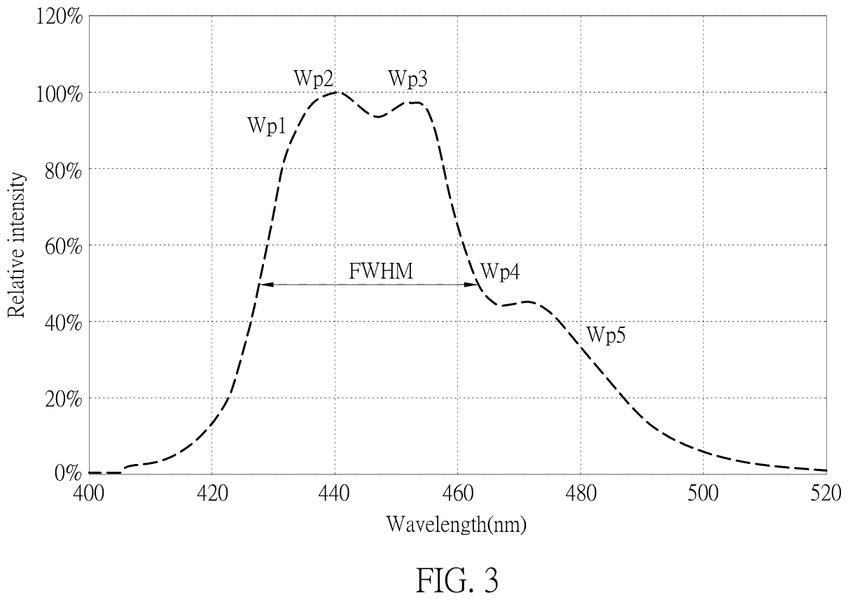

Reference can be made to FIG. 2 and FIG. 3 for better understanding of positional relationships of each well layer. FIG. 2 is a relation diagram of indium concentrations of a light-emitting stacked layer according to a first embodiment of the present disclosure, and is obtained by analyzing the indium concentration of each well layer 321 and an indium concentration of each barrier layer 320 in the light-emitting stacked layer 32 via an SIMS (secondary-ion mass spectrometry) technique along a direction from the p-type semiconductor layer 31 to the n-type semiconductor layer 30. FIG. 3 is a waveform diagram of a blue spectrum of the embodiment shown in FIG. 2. Theoretically, Wp2, Wp3, Wp4, and Wp5 in FIG. 3 respectively and substantially correspond in position to peaks of sub-light beams generated by the electrons and the holes in the second well layer 321b, the third well layer 321c, the fourth well layer 321d, and the fifth well layer 321e during the carrier recombination process. In the embodiment of FIG. 2, the quantity (i.e., the number m) of the well layers 321 is eleven, and a quantity of the barrier layers 320 is twelve. However, the present disclosure is not limited thereto. In order to better illustrate the positional relationships of each well layer, only the position of the well layers will be described in the descriptions below. In the embodiment of FIG. 2, the third well layer 321c is disposed in the middle section of the light-emitting stacked layer 32, and is preferably disposed adjacent to the middle position of the light-emitting stacked layer 32. The two second well layers 321b are respectively disposed on the two sides of the third well layer 321c. One or both of the fifth well layer 321e and the fourth well layer 321d are disposed in the n-side proximate section of the light-emitting stacked layer 32. For example, the fifth well layer 321e can be the well layer that is closest to the n-type semiconductor layer 30, and the fourth well layer 321d can be second closest or third closest to the n-type semiconductor layer 30. Due to the quantity and the position of the fourth well layer 321d and/or the fifth well layer 321e, a full width at half maximum of the blue spectrum generated by the light-emitting diode Z12 can be widened along a long wave direction. Referring to FIG. 2, apart from the forth well layer 321d, the well layer that is closest to the fifth well layer 321e can also be the second well layer 321b in some embodiments. Such adjustment has little influence on the spectrum when the quantity of the at least one fourth well layer 321d is merely one.

In an exemplary embodiment (as the embodiment of FIG. 2), the light-emitting stacked layer 32 further includes a first well layer 321a. An indium concentration of the first well layer 321a is defined as C1, and C1 is less than C2. The first well layer 321a is disposed in the p-side proximate section. In this way, Wp1 is prevented from being too high in intensity, and the full width at half maximum of the blue spectrum generated by the light-emitting diode Z12 can be widened along a short wave direction.

Theoretically, the broadband blue spectrum generated in the above-mentioned embodiment has five peak inflection points (i.e., Wp1, Wp2, Wp3, Wp4, and Wp5), which respectively and substantially correspond to the sub-light beams generated by the first well layer 321a, the second well layer 321b, the third well layer 321c, the fourth well layer 321d, and the fifth well layer 321e. Due to the relative position and the relative intensity of each peak inflection point, at least three of the peak inflection points are visually observable from the waveform diagram. The obvious peak inflection points are the peak inflection points Wp2, Wp3, and Wp4. A second wavelength that corresponds to the peak inflection point Wp2 ranges between 430 nm and 460 nm, and has a second spectrum intensity. For ease of illustration, each spectrum diagram in the following descriptions is normalized based on the second spectrum intensity. A third wavelength that corresponds to the peak inflection point Wp3 ranges between 445 nm and 475 nm, and has a third spectrum intensity. A difference between the third wavelength and the second wavelength ranges from 5 nm to 30 nm. In the present embodiment, a fourth wavelength that corresponds to the peak inflection point Wp4 ranges between 455 nm and 485 nm, and has a fourth spectrum intensity. A difference between the fourth wavelength and the second wavelength ranges from 20 nm to 50 nm. Regarding ratios of the second spectrum intensity, the third spectrum intensity, and the fourth spectrum intensity, detailed descriptions thereof will be provided below.

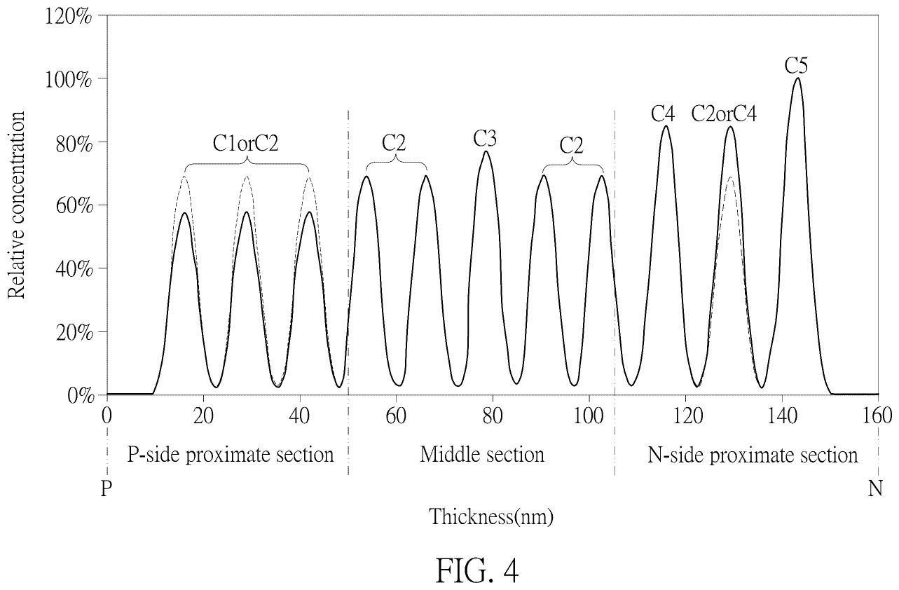

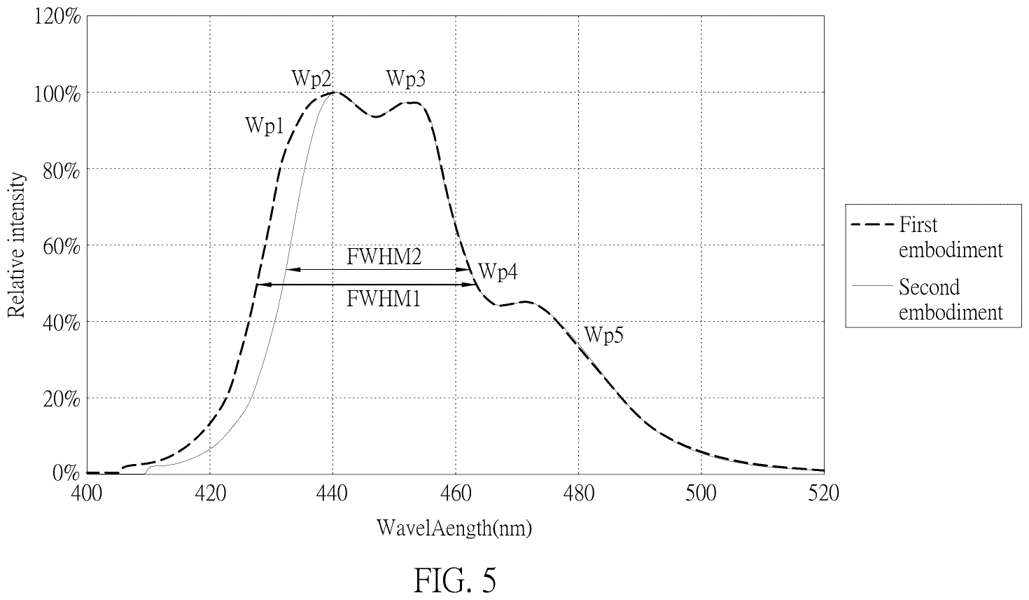

Referring to FIG. 4 and FIG. 5, FIG. 4 is a relation diagram of indium concentrations of a light-emitting stacked layer according to a second embodiment of the present disclosure, and FIG. 5 is a waveform diagram of a blue spectrum of the embodiment shown in FIG. 4. The second embodiment is different from the first embodiment in that, without the first well layer 321a, the well layer that is disposed in the p-side proximate section can be the second well layer 321b. It can be observed from FIG. 5 that, through configuring the first well layer 321a to be less than the C2 indium concentration of the second well layer 321b, the full width at half maximum of the blue spectrum generated by the light-emitting diode Z12 is widened along the short wave direction. However, the main waveform of the blue light is not affected.

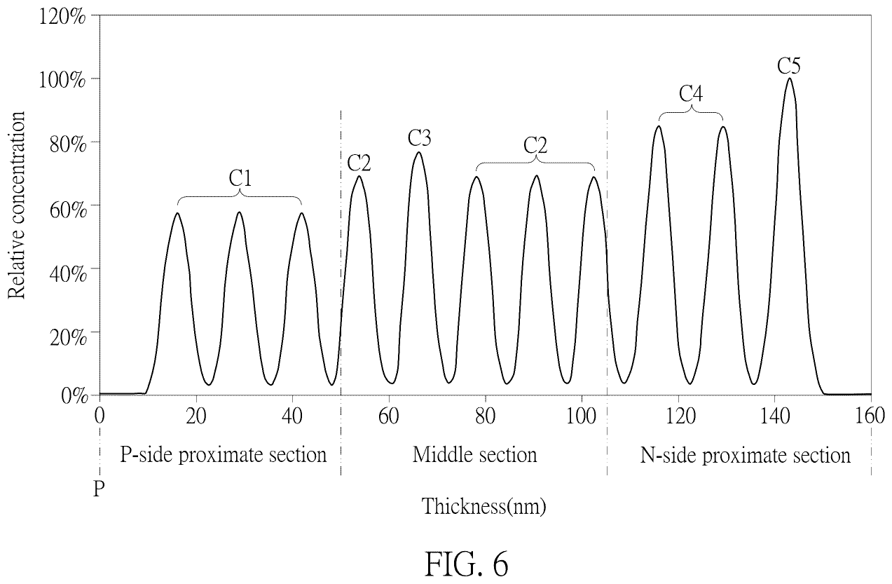

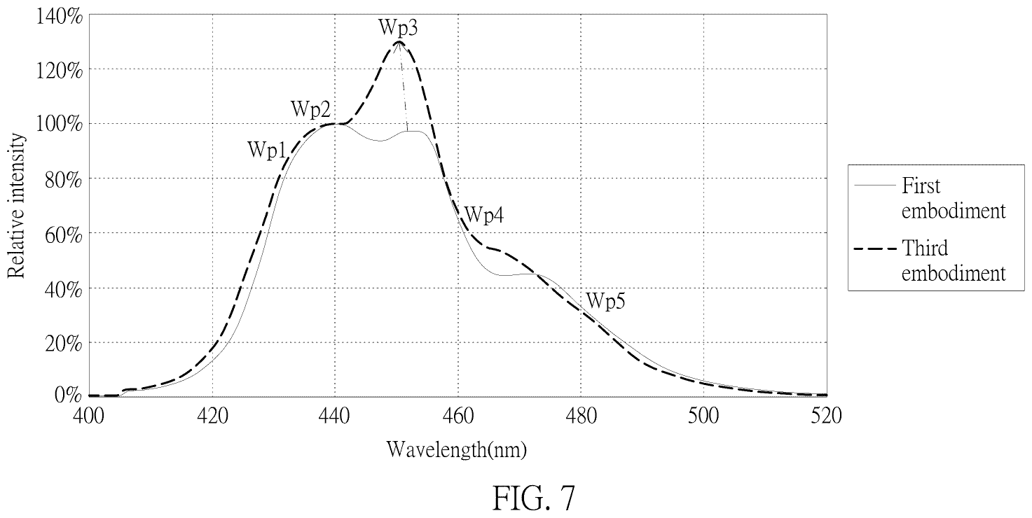

Referring to FIG. 6 and FIG. 7, FIG. 6 is a relation diagram of indium concentrations of a light-emitting stacked layer according to a third embodiment of the present disclosure, and FIG. 7 is a waveform diagram of a blue spectrum of the embodiment shown in FIG. 6. In the third embodiment, the third well layer 321c is still disposed in the middle section, and is adjacent to the middle position of the light-emitting stacked layer 32. However, compared with the first embodiment, the third well layer 321c is closer to the p-type semiconductor layer 31 in the third embodiment, thereby enabling the third spectrum intensity of the peak inflection point Wp3 to be increased. In some embodiments, the barrier layers 320 between the third well layer 321c and the p-type semiconductor layer 31 can be increased in thickness to reduce the intensity of the peak inflection point Wp3. For example, a total thickness of the barrier layers 320 between the third well layer 321c and the p-type semiconductor layer 31 is greater than a total thickness of the barrier layers 320 between the third well layer 321c and the n-type semiconductor layer 30. Alternatively, a thickness of the barrier layers 320 in the p-side proximate section is greater than a thickness of the barrier layers 320 in the n-side proximate section.

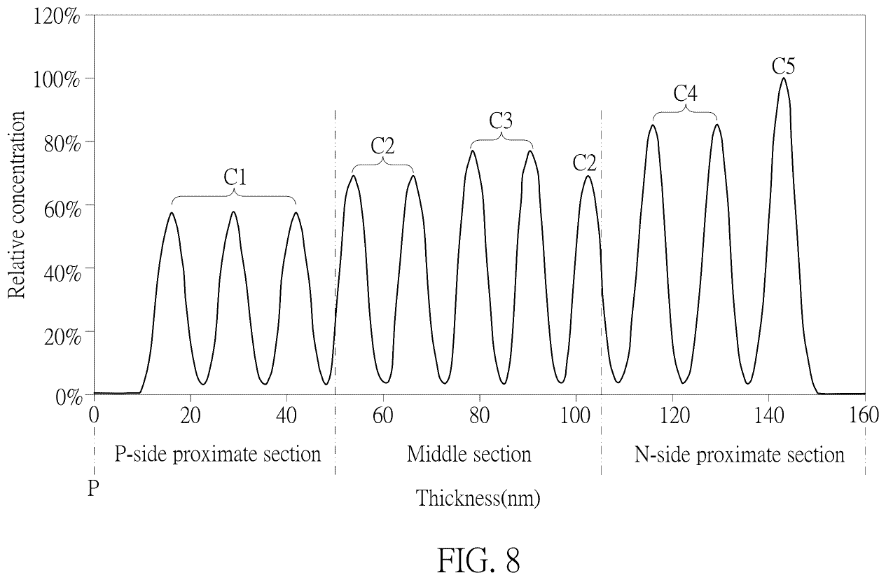

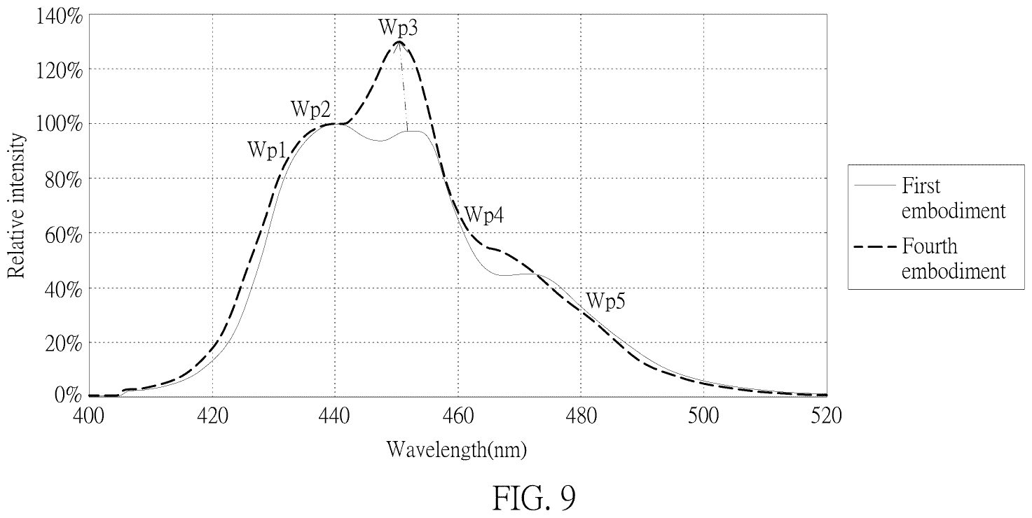

Referring to FIG. 8 and FIG. 9, FIG. 8 is a relation diagram of indium concentrations of a light-emitting stacked layer according to a fourth embodiment of the present disclosure, and FIG. 9 is a waveform diagram of a blue spectrum of the embodiment shown in FIG. 8. In the fourth embodiment, the quantity of the at least one third well layer 321c is two. In addition, the two third well layers 321c are disposed in the middle section, and are adjacent to the middle position of the light-emitting stacked layer 32. Compared with the first embodiment, the third spectrum intensity of the peak inflection point Wp3 is increased. In some embodiments, through increasing the thickness of the barrier layers 320 between the third well layers 321c and the p-type semiconductor layer 31, the intensity of the peak inflection point Wp3 can be reduced.

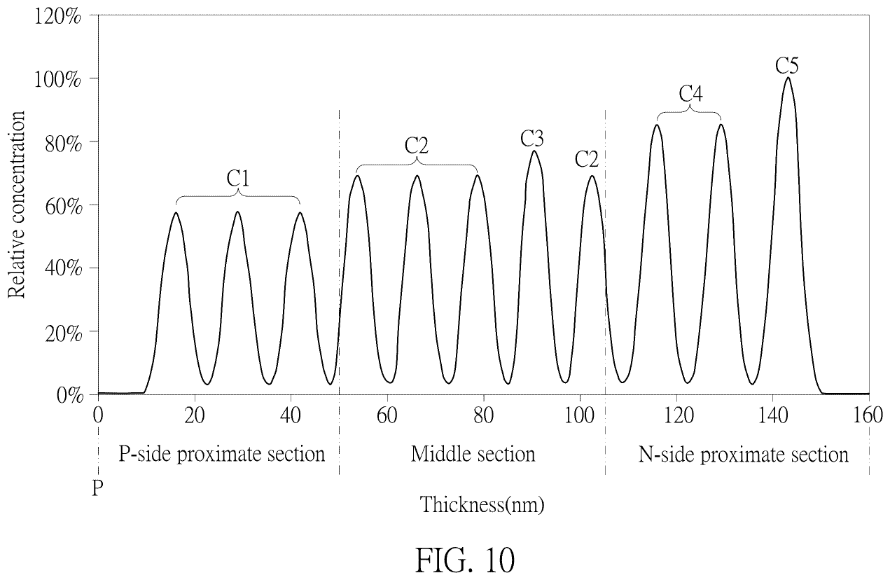

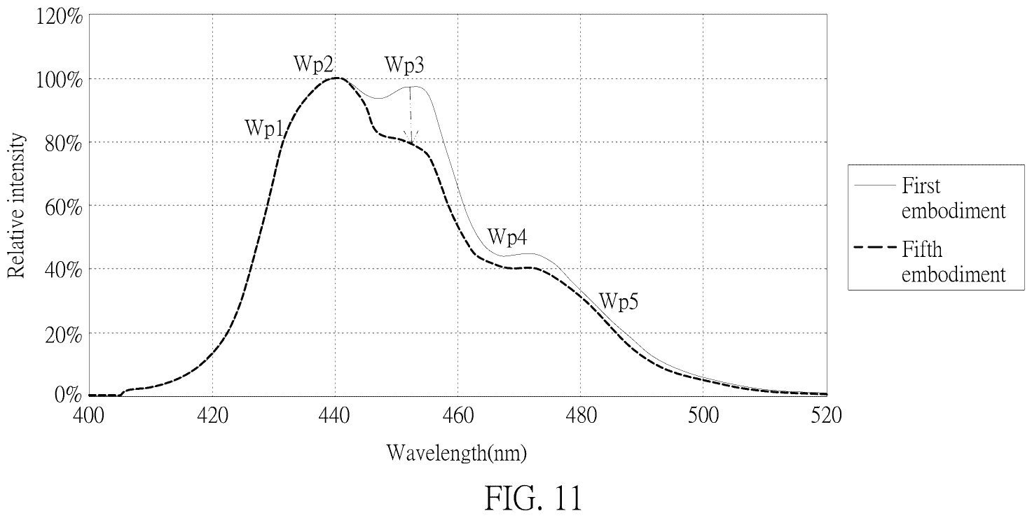

Referring to FIG. 10 and FIG. 11, FIG. 10 is a relation diagram of indium concentrations of a light-emitting stacked layer according to a fifth embodiment of the present disclosure, and FIG. 11 is a waveform diagram of a blue spectrum of the embodiment shown in FIG. 10. In the fifth embodiment, the third well layer 321c is still disposed in the middle section, and is adjacent to the middle position of the light-emitting stacked layer 32. Compared with the first embodiment, the third well layer 321c is closer to the n-type semiconductor layer 30. At this time, the peak inflection point Wp3 is reduced in intensity (as compared with the first embodiment). In some embodiments, through decreasing the thickness of the barrier layers 320 between the third well layer 321c and the p-type semiconductor layer 31, the intensity of the peak inflection point Wp3 can be increased.

In some embodiments of the present disclosure, taking the requirement of obtaining the full-spectrum white light after the wavelength conversion layer Z13 performs wavelength conversion on the light of the light-emitting diode Z12 into consideration, a waveform of the broadband blue spectrum of the light-emitting diode Z12 has multiple peak inflection points. Based on the second spectrum intensity that corresponds to the peak inflection point Wp2, a ratio between the third spectrum intensity that corresponds to the peak inflection point Wp3 and the second spectrum intensity that corresponds to the peak inflection point Wp2 preferably ranges from 60% to 130%, and a ratio between the fourth spectrum intensity that corresponds to the peak inflection point Wp4 and the second spectrum intensity that corresponds to the peak inflection point Wp2 preferably ranges from 30% to 80%. In certain embodiments, a ratio between a first spectrum intensity that corresponds to the peak inflection point Wp1 and the second spectrum intensity that corresponds to the peak inflection point Wp2 ranges from 30% to 80%, and a ratio between a fifth spectrum intensity that corresponds to the peak inflection point Wp5 and the second spectrum intensity that corresponds to the peak inflection point Wp2 ranges from 10% to 50%.

In some embodiments of the present disclosure, in order for the light-emitting diode Z12 to better cooperate with a fluorescent powder for emission of the full-spectrum white light, the indium concentrations of different well layers are configured as follows. In the light-emitting stacked layer 32, based on the C5 indium concentration of the fifth well layer 321e being 100%, a concentration ratio between the C2 indium concentration and the C5 indium concentration ranges from 60% to 75%, a concentration ratio between the C3 indium concentration and the C5 indium concentration ranges from 70% to 85%, and a concentration ratio between the C4 indium concentration and the C5 indium concentration ranges from 75% to 95%. In certain embodiments, a concentration ratio between the C1 indium concentration and the C5 indium concentration ranges from 40% to 60%. Furthermore, based on C5 being 100%, a difference between any two of C1, C2, C3, C4, and C5 is 4% or more.

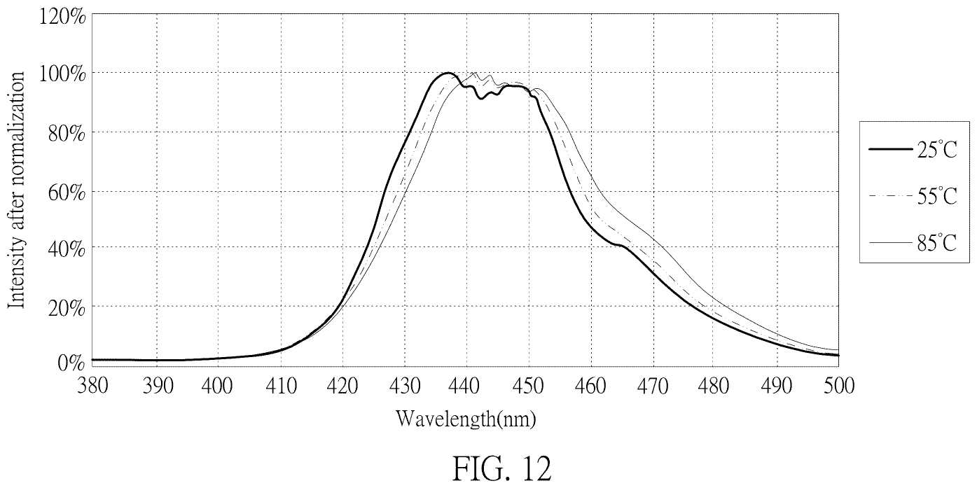

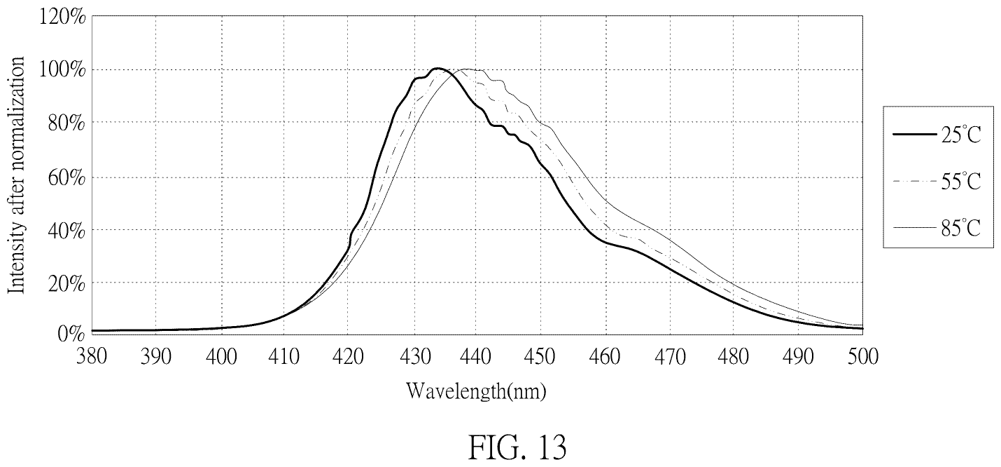

Reference is made to FIG. 12 and FIG. 13, each of which is a waveform diagram of a blue spectrum under different temperatures according to one embodiment of the present disclosure. An operating current density in the embodiment of FIG. 12 is 120 mA/mm², and an operating current density in the embodiment of FIG. 13 is 300 mA/mm². As shown in FIG. 12, within a conventional operating temperature range of between 10° C. and 110° C. (only spectrum waveforms of common operating temperatures are shown in FIG. 12 and FIG. 13, but the present disclosure is not limited thereto), temperature-induced changes in a wavelength that corresponds to the peak inflection point Wp2 (one of the main characteristic peaks) are generally less than or equal to 0.10 nm/° C., and can even be less than 0.07 nm/° C. in certain embodiments. As shown in FIG. 13, the temperature-induced changes in the wavelength that corresponds to the peak inflection point Wp2 are generally less than or equal to 0.15 nm/° C., and can even be less than 0.11 nm/° C. in certain embodiments.

As shown in FIG. 12, temperature-induced changes in a wavelength that corresponds to the peak inflection point Wp3 (another one of the main characteristic peaks) are substantially the same as those of the peak inflection point Wp2, and can serve as an important factor of consideration. Based on the intensity of the peak inflection point Wp2 being 100%, temperature-induced changes in an intensity ratio between the peak inflection point Wp3 and the peak inflection point Wp2 are generally less than or equal to 0.01%/°° C., and can even reach 0 nm/° C. in certain embodiments. As shown in FIG. 13, based on the intensity of the peak inflection point Wp2 being 100%, the temperature-induced changes in the intensity ratio between the peak inflection point Wp3 and the peak inflection point Wp2 are generally less than or equal to 0.15%/° C., and can even reach 0.10 nm/° C. in certain embodiments.

### Beneficial Effects of the Embodiments

In conclusion, in the light-emitting diode and the white light-emitting device provided by the present disclosure, the at least one second well layer, the at least one third well layer, the at least one fourth well layer, and the at least one fifth well layer are configured to have different indium concentrations, such that the C2 indium concentration, the C3 indium concentration, the C4 indium concentration, and the C5 indium concentration (C5>C4>C3>C2) are respectively defined. Furthermore, the light-emitting stacked layer is configured to include the n-side proximate section, the middle section, and the p-side proximate section. The at least one third well layer is disposed in the middle section. When the quantity of the at least one second well layer is two and the quantity of the at least one third well layer is one, the third well layer is disposed between the two second well layers. Accordingly, the blue spectrum can be widened, and the stability of the blue spectrum of the light-emitting diode can be improved irrespective of changes in current densities or temperature. While the light emitted by the light-emitting diode through the wavelength conversion layer is the full-spectrum white light, the full-spectrum white light formed in this manner is also more stable relative to the operating temperature.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A light-emitting diode, which is capable of emitting a light beam having a broadband blue spectrum, comprising:
a p-type semiconductor layer;
an n-type semiconductor layer; and
a light-emitting stacked layer disposed between the p-type semiconductor layer and the n-type semiconductor layer, wherein the light-emitting stacked layer includes a plurality of well layers and a plurality of barrier layers that are alternately stacked with each other; wherein the light-emitting stacked layer includes at least one second well layer, at least one third well layer, at least one fourth well layer, and at least one fifth well layer that have different indium concentrations, such that a C2 indium concentration, a C3 indium concentration, a C4 indium concentration, and a C5 indium concentration are respectively defined, and a relationship of the indium concentrations is C5>C4>C3>C2;
wherein the light-emitting stacked layer is configured to include three sections along a thickness direction; wherein first three ones of the well layers that are in proximity to the n-type semiconductor layer and adjacent ones of the barrier layers are defined as an n-side proximate section, first three ones of the well layers that are in proximity to the p-type semiconductor layer and adjacent ones of the barrier layers are defined as a p-side proximate section, and the well layers and the barrier layers that are disposed between the n-side proximate section and the p-side proximate section are defined as a middle section;
wherein the at least one third well layer is disposed in the middle section; wherein, when a quantity of the at least one second well layer is two and a quantity of the at least one third well layer is one, the two second well layers are respectively disposed on two sides of the third well layer.

2. The light-emitting diode according to claim 1, wherein the at least one fourth well layer or the at least one fifth well layer is disposed in the n-side proximate section.

3. The light-emitting diode according to claim 1, wherein a ratio between the C2 indium concentration and the C5 indium concentration ranges from 60% to 75%, a ratio between the C3 indium concentration and the C5 indium concentration ranges from 70% to 85%, and a ratio between the C4 indium concentration and the C5 indium concentration ranges from 75% to 95%.

4. The light-emitting diode according to claim 1, wherein the at least one second well layer is disposed in the p-side proximate section.

5. The light-emitting diode according to claim 1, wherein the light-emitting stacked layer further includes at least one first well layer, an indium concentration of the at least one first well layer is defined as C1, and C1 is less than C2; wherein the at least one first well layer is disposed in the p-side proximate section.

6. The light-emitting diode according to claim 5, wherein a ratio between the C1 indium concentration and the C5 indium concentration ranges from 40% to 60%.

7. The light-emitting diode according to claim 1, wherein the broadband blue spectrum has a second peak inflection point within a range of between 430 nm and 460 nm, and the second peak inflection point has a second wavelength and a second spectrum intensity that correspond to the second peak inflection point; wherein the broadband blue spectrum has a third peak inflection point within a range of between 445 nm and 475 nm, the third peak inflection point has a third wavelength and a third spectrum intensity that correspond to the third peak inflection point, and a difference between the third wavelength and the second wavelength ranges from 5 nm to 30 nm; wherein the broadband blue spectrum has a fourth peak inflection point within a range of between 455 nm and 485 nm, the fourth peak inflection point has a fourth wavelength and a fourth spectrum intensity that correspond to the fourth peak inflection point, and a difference between the fourth wavelength and the second wavelength ranges from 20 nm to 50 nm.

8. The light-emitting diode according to claim 7, wherein, based on the second spectrum intensity, a ratio between the third spectrum intensity and the second spectrum intensity ranges from 60% to 130%, and a ratio between the fourth spectrum intensity and the second spectrum intensity ranges from 30% to 80%.

9. The light-emitting diode according to claim 7, wherein a variation of the second wavelength relative to a temperature of between 10° C. and 110° C. is less than or equal to 0.10 nm/° C.

10. The light-emitting diode according to claim 7, wherein, based on the second spectrum intensity, a variation of a ratio between the third spectrum intensity and the second spectrum intensity relative to a temperature of between 10° C. and 110° C. is less than or equal to 0.15%/° C.

11. A white light-emitting device, comprising:
a substrate;
a light-emitting diode capable of emitting a light beam having a broadband blue spectrum, wherein the light-emitting diode is disposed on the substrate, and includes:
a p-type semiconductor layer;
an n-type semiconductor layer; and
a light-emitting stacked layer disposed between the p-type semiconductor layer and the n-type semiconductor layer, wherein the light-emitting stacked layer includes a plurality of well layers and a plurality of barrier layers that are alternately stacked with each other; wherein the light-emitting stacked layer includes at least one second well layer, at least one third well layer, at least one fourth well layer, and at least one fifth well layer that have different indium concentrations, such that a C2 indium concentration, a C3 indium concentration, a C4 indium concentration, and a C5 indium concentration are respectively defined, and a relationship of the indium concentrations is C5>C4>C3>C2;
wherein the light-emitting stacked layer is configured to include three sections along a thickness direction; wherein first three ones of the well layers that are in proximity to the n-type semiconductor layer and adjacent ones of the barrier layers are defined as an n-side proximate section, first three ones of the well layers that are in proximity to the p-type semiconductor layer and adjacent ones of the barrier layers are defined as a p-side proximate section, and the well layers and the barrier layers that are disposed between the n-side proximate section and the p-side proximate section are defined as a middle section;
wherein the at least one third well layer is disposed in the middle section; wherein, when a quantity of the at least one second well layer is two and a quantity of the at least one third well layer is one, the two second well layers are respectively disposed on two sides of the third well layer; and
a wavelength conversion layer, wherein the wavelength conversion layer covers the light-emitting diode.

12. The white light-emitting device according to claim 11, wherein the at least one fourth well layer or the at least one fifth well layer is disposed in the n-side proximate section.

13. The white light-emitting device according to claim 11, wherein a ratio between the C2 indium concentration and the C5 indium concentration ranges from 60% to 75%, a ratio between the C3 indium concentration and the C5 indium concentration ranges from 70% to 85%, and a ratio between the C4 indium concentration and the C5 indium concentration ranges from 75% to 95%.

14. The white light-emitting device according to claim 11, wherein the at least one second well layer is disposed in the p-side proximate section.

15. The white light-emitting device according to claim 11, wherein the light-emitting stacked layer further includes at least one first well layer, an indium concentration of the at least one first well layer is defined as C1, and C1 is less than C2; wherein the at least one first well layer is disposed in the p-side proximate section.

16. The white light-emitting device according to claim 15, wherein a ratio between the C1 indium concentration and the C5 indium concentration ranges from 40% to 60%.

17. The white light-emitting device according to claim 11, wherein the broadband blue spectrum has a second peak inflection point within a range of between 430 nm and 460 nm, and the second peak inflection point has a second wavelength and a second spectrum intensity that correspond to the second peak inflection point; wherein the broadband blue spectrum has a third peak inflection point within a range of between 445 nm and 475 nm, the third peak inflection point has a third wavelength and a third spectrum intensity that correspond to the third peak inflection point, and a difference between the third wavelength and the second wavelength ranges from 5 nm to 30 nm; wherein the broadband blue spectrum has a fourth peak inflection point within a range of between 455 nm and 485 nm, the fourth peak inflection point has a fourth wavelength and a fourth spectrum intensity that correspond to the fourth peak inflection point, and a difference between the fourth wavelength and the second wavelength ranges from 20 nm to 50 nm.

18. The white light-emitting device according to claim 17, wherein, based on the second spectrum intensity, a ratio between the third spectrum intensity and the second spectrum intensity ranges from 60% to 130%, and a ratio between the fourth spectrum intensity and the second spectrum intensity ranges from 30% to 80%.

19. The white light-emitting device according to claim 17, wherein a variation of the second wavelength relative to a temperature of between 10° C. and 110° C. is less than or equal to 0.10 nm/° C.

20. The white light-emitting device according to claim 17, wherein, based on the second spectrum intensity, a variation of a ratio between the third spectrum intensity and the second spectrum intensity relative to a temperature of between 10° C. and 110° C. is less than or equal to 0.15%/° C.
